(19) United States
(12) Patent Application Publication
(10) Pub. No.: US 2003/0095465 A1
(43) Pub. Date: May 22, 2003

(54) High area efficient data line architecture

(75) Inventors: Chun Shiah, Taichung (TW); Ming-Hung Wang, Hsi Chu (TW); Chiun-Chi Shen, Chutung (TW)

Correspondence Address: GEORGE O. SAILE & ASSOCIATES, 28 DAVIS AVENUE, POUGHKEEPSIE, NY, 12603, US

(73) Assignee: Etron Technology, Inc.

(21) Appl. No.: 09/884,657

(22) Filed: Jun. 21, 2001

(51) Int. Cl. G11C 8/12

(52) U.S. Cl. 365/230.06

(57) ABSTRACT

A hierarchical bit line selection circuit is connected between a plurality of pairs of bit lines of a plurality of sub-arrays of a random access memory and a data line sense amplifier. The bit line selection circuit has a bit line selector circuit to selectively couple one pair of bit lines of the plurality of bit lines of each sub-array to the pair of local data lines. The bit line selection circuit further has a local data line selector circuit to select one of a plurality of pairs of local data lines to be connected to a pair main data lines that are connected to the inputs of the data line sense amplifier.

### BACKGROUND OF THE INVENTION

1. Field of the Invention

This invention relates to random access memories (RAM) such as dynamic random access memory (DRAM), static random access memory (SRAM), read only memory (ROM) and other memory structures. More particularly, this invention relates to circuits and methods of coupling bit line pairs containing a memory data signal to a data line sense amplifier such that the data line sense amplifier can sense the data memory signal and amplify the data memory signal to create a memory data bit.

2. Description of Related Art

Random access memories (RAM) such as a dynamic random access memory (DRAM), static random access memory (SRAM), and read only memory (ROM) are generally structured as shown in FIGS. 1a-1c.

A memory integrated circuit is shown in FIG. 1a as having multiple independent memory array units MAU. Each memory array unit is formed of groups of memory blocks MB<0 >, . . . , MB<n>. The memory block MB<R>acts as a redundant or spare block that can be configured to replace non-functioning areas of the remaining memory block MB<0>, . . . , MB<n>.

The bank of main data line sense amplifiers MDQSA sense the memory data signal from the selected memory blocks MB<0>, . . . , MB<n>, amplify, and convert the memory data signal to a signal level acceptable by the I/O circuitry of the memory integrated circuit. The input to each main data line sense amplifier of the bank of data line sense amplifiers MDQSA is a pair of main data lines MDQ that are connected to each of the memory blocks MB<0>, . . . , MB<n>.

Each memory block MB<0>, . . . , MB<n>is divided into a group of memory segments MSEG<0>, . . . , MSEG<n>. As shown in FIG. 1b, each memory segment is constructed of multiple sub-arrays. The structure of each memory sub-array, as shown in FIG. 1c has an array of memory cells arranged in rows and columns. At the periphery of the array of memory cells is a bank of bit line sense amplifiers SA. The output of each of the bit line sense amplifiers is coupled to a pair of local data lines LDQ1, . . . , LDQ4 through the bit switches BS1, . . . , BSn. In turn, the local data lines LDQ1, . . . , LDQ4 are selectively coupled to the main data lines MDQ1, . . . , MDQ4 and thus to the main data line sense amplifiers.

The main data switches MDSW1, . . . , MDSWn provide the selective connecting of the local data lines LDQ1, . . . , LDQ4 to the main data line sense amplifiers. As shown, each main data line MDQ1, . . . , MDQ4 is connected through a main data switch MDSW1, . . . , MDSWn to the local data lines LDQ1, . . . , LDQ4 for each memory block MB<0>, . . . , MB<n>. When memory cells within a memory block MB<0>, . . . , MB<n>are selected, the appropriate bit switches BS0, . . . , BSn and the appropriate main data switches MDSW1, . . . , MDSWn are activated to insure that the selected memory cells are coupled to the main data line sense amplifiers MDQSA.

To avoid corruption of the memory data signals from the selected data cells, the bit switches BS0, . . . , BSn and the main data switches MDSW1, . . . , MDSWn must be activated such that only one memory cell is coupled to a main data line sense amplifier MDQSA.

The rows of memory cells within each sub-array are activated by the word line control signals WL0, WL1, . . . , WLi.

The memory cells that are activated by a selected word line WL0, WL1, . . . , WLi-1, WLi transfer a memory data signal to the bit lines BL00, \overline{BL00}, . . . , BLmn, \overline{BLmn}. In a DRAM structure, as is known in the art, the bit lines are paired with one bit line BL00, . . . , BLmn receiving the charge from the activated memory cell, while the complemented bit line BL00, . . . , BLmn acts as a voltage reference. The pairs of bit lines BL00, \overline{BL00}, . . . BLmn, \overline{BLmn}_ are connected to bit line sense amplifiers SA. The bit line sense amplifier senses and amplifies the memory data signal to a suitable level for detection.

The paired bit lines BL00, \overline{BL00}, BL01, \overline{BL01}, . . . , BLmn, \overline{BLmn} are coupled through the bit switch circuit to the local data line pairs LDQ1, LDQ2. The bit select signals BS1, . . . , BSn are connected to the bit switch circuit to select one pair of the paired bit lines BL00, \overline{BL00}, BL01, \overline{BL01}, . . . , BLmn, \overline{BLmn} to be connected to each of the pairs of local data lines LDQ1, LDQ2.

The bit switch is formed by pairs of metal oxide semiconductor (MOS) transistors M5 and M6, M7 and M8, M9 and M10. The drains of the pairs of MOS transistors M5 and M6, M7 and M8, M9 and M10 are connected respectively to the bit lines BL00 and \overline{BL00}, BL01 and \overline{BL01}, BLmn and \overline{BLmn}. The sources of the pairs of MOS transistors MS and M6, M7 and M8 are connected to the local data lines LDQ1 and the sources of the pair of MOS transistors M9 and MIO are connected to the local data lines LDQ2. It is apparent that the memory sub-array has any number of paired bit lines connected to any number of pairs of MOS transistors within the bit switch. Further, it is apparent that multiple pairs of local data lines could be included in the structure shown.

The gates of the pairs of MOS transistors M5 and M6, M7 and M8, M9 and MIO are connected together and to the bit switch control lines BS1, . . . , BSn. The activation of the bit switch control lines BS1, . . . , BSn directs which of the pairs of bit lines BL00 and \overline{BL00}, BL01 and \overline{BL01}, and BLmn and \overline{BLmn} are to be coupled to the local data lines LDQ1 and LDQ2.

The local data lines LDQ1 and LDQ2 are connected to the local data line selection circuit LDQSEL The local data line enabling circuit LDQSEL connects the pairs of local data lines LDQ1 and LDQ2 respectively to the pairs of main data lines MDQ1 and MDQ2. The pairs of main data lines MDQ1 and MDQ2 are further connected to the main data line sense amplifiers MDQSA1 and MDQSA2.

The outputs of the main data line sense amplifiers MDQSA1 and MDQSA2 are the inputs to the data selector DSEL The data selector DSEL chooses one of the outputs of the main data line sense amplifiers MDQSA1 and MDQSA2 as the memory bit to be placed at the Input/output terminal 110 for transfer to other circuitry.

The data selector DSEL is controlled by the select address signal SELADDR When the select address signal SELADDR is set to a first state (0) the output of the main data line sense amplifier MDQSA2 is transferred to the Input/output terminal I/O. Conversely, when the select address signal SELADDR is set to a second state (1) the output of the main data line sense amplifier MDQSA1 is transferred to the I/O terminal.

The main data lines swatches MDSW1 and MDSW2 are respectively formed of the pairs of MOS transistors M3 and M4, M1 and M2. The drains of the pair of MOS transistors M3 and M4 are connected to the local data line LDQ1. The sources of the MOS transistors M3 and M4 are connected to the main data lines MDQ1 and thus to the main data line sense amplifier MDQSA1. The sources of the MOS transistors M1 and M2 are connected to the main data line MDQ2 and thus to the main data line sense amplifier MDQSA2. The gates of the MOS transistors M3 and M4 are connected together and to the switch enable control line SWEN The switch enable control signal SWEN1 activates the MOS transistors M3 and M4. The gates of the MOS transistors M1 and M2 are connected together and to the switch enable control line SWEN. The switch enable control signal SWEN2 activates the MOS transistors M1 and M2.

The following is an explanation of a read operation of the memory sub-array of the prior art. If the word line WL0 is brought to a voltage level sufficient to activate the memory cells MC1, MC2, and MC3, the charge from memory cell MCI migrates to the bit line BL00, the charge from memory cell MC2 migrates to the bit line BL01, and the charge from memory cell MC3 migrates to bit line BLmn. The bit lines \overline{BL00}, \overline{BL01},_and \overline{BLmn} respectively are charged to act as a reference voltage source for the bit lines BL00, BL01 and BLmn. The sense amplifier SA senses the charge and amplifies the voltage difference between the bit lines BL00 and \overline{BL00}, BL01 and BL01, BLmn and BLmn to an appropriate voltage level detectable by the main data line sense amplifiers MDQSA1 and MDQSA2. One of the bit switch control lines BS1, . . . , BSn is activated to couple the pairs of bit lines BL00 and \overline{BL00}, BL01 and \overline{BL01}, BLmn and \overline{BLmn} to the pairs of local data lines LDQ1 and LDQ2. For instance, if the bit switch signal BS1 is activated, the MOS transistors M5 and M6 are turned on and the memory data signal present on the bit lines BL00 and \overline{BL00}_is coupled to the pair of local data lines LDQ1. Also, when the bit switch signal BSI is activated, the MOS transistors M9 and M10 are turned on and the memory data signal present on the bit lines BL01 and \overline{BL01} is coupled to the pair of local data lines LDQ2.

If one of the memory data signals present on the local data lines LDQ1 and LDQ2 is the memory data signal to be sensed and amplified to form the data bit at the Input/output terminal I/O, the main data switches are activated by the switch enable control lines SWEN1 and SWEN2 to transfer the memory data signals respectively from the pair of local data lines LDQ1 and LDQ2 to the pair of main data lines MDQ1 and MDQ2. When the switch enable control lines SWEN1 and SWEN2 are activated the MOS transistors M3 and M4, and M1 and M2 are respectively turn on to couple the pair of local data lines LDQ1 to the pair of main data lines MDQ1 and the pair of local data lines LDQ2 to the pair of main data lines MDQ2.

The select address signals SELADDR is then set to activate either of the MOS transistors M21 or M22 to transfer the memory data bits from the pair of memory data lines MDQ1 or the pair of memory data lines MDQ2 to the Input/output terminal 110.

The structure of the prior art allows multiple memory data signals to be read from a memory sub-array. However, this requires duplicated main data lines MDQ1 and MDQ2, duplicated data line sense amplifiers MDQSA1 and MDQSA2, and duplicated data selector switches DSEL. Further, the switch control circuitry is more complex to provide the control signals for the select address SELADDR.

“A 286 rnm2 256 Mb DRAM with×32 Both-Ends DQ,” Watanabe et al., IEEE Journal Of Solid-State Circuits Vol. 31, NO 4, April 1996, pp. 567-574, describes a 256 Mb DRAM chip architecture which provides up to ×32 wide organization. In order to minimize the die size, three techniques: an exchangeable hierarchical data line structure; an irregular sense amp layout; and a split address bus with local redrive scheme in the both-ends DQ are introduced.

“A 220-mm². Four- and Eight-Bank, 256-Mb SDRAM with Single-Sided Stitched WL Architecture”,₇ Kirihata, et al., IEEE Journal Of Solid-State Circuits, VOL 33, NO. 11, November 1998, pp. 1711-1719; and “Multiple Twisted Data Line Techniques for Multigigabit DRAM's”, Min et al., IEEE Journal Of Solid-State Circuits, VOL. 34, NO. 6, JUNE 1999, pp. 856-865 provide a description of hierarchical data line structures for DRAM's.

U.S. Pat. No. 5,812,473 (Tsai) discloses a Synchronous DRAM with alternated data line sensing.

U.S. Pat. No. 5,546,349 (Watanabe et al.) discloses an exchangeable hierarchical data line structure.

U.S. Pat. No. 5,877,994 (Mueller et al.) discloses a space-efficient MDQ switch placement.

U.S. Pat. No. 5,418,737 (Tran) discloses a DRAM with sub data lines and match lines for test

U.S. Pat. No. 5,859,793 (Santani et al.) discloses a synchronous semiconductor memory device with essentially parallel data lines which prevents to misread due to the parasitic capacitance.

U.S. Pat. No. 5,909,388 (Mueller) describes dynamic random access memory circuit with stitched word lines to lower resistance in the word lines. The DRAM further includes a hierarchical data line structure with a set of bit lines, a set of master data lines, low resistance conductors of the word lines, a set of local data lines, and a set of master line-to-switch connectors are formed from at least four different conductor layers of the memory circuit.

### SUMMARY OF THE INVENTION

An object of this invention is to provide a circuit for selectively coupling pairs of bit lines of a RAM to a main data line sense amplifier to convert a memory data signal present on the selected pair of bit lines to a memory bit at an output terminal of the main data line sense amplifier.

To accomplish this and other objects, a hierarchical bit line selection circuit is connected between a plurality of pairs of bit lines of a plurality of sub-arrays of a random access memory and a data line sense amplifier. The bit line selection circuit has a bit line selector circuit to selectively couple one pair of bit lines of the plurality of bit lines of each sub-array to the pair of local data lines. The bit line selection circuit further has a local data line selector circuit to select one of a plurality of pairs of local data lines to be connected to a pair of main data lines. The pair of main data lines are connected to the inputs of the data line sense amplifier.

The bit line selector circuit is formed of multiple switches, whereby each switch has a first pair of terminals connected to one pair of the pairs of bit lines, a second pair of terminals connected to one of the pair of local data lines, and a control terminal to selectively connect the first pair of terminals to the second pair of terminals to couple the pair of bit lines to the pair of local data lines. Each switch of the bit line selector circuit is formed from a pair of MOS transistors, whereby the pair of MOS transistors has a pair of drains connected the pair of bit lines, a pair of sources connected to the pair of local data lines, and a pair of gates connected together to form the control terminal. The control terminal is connected to the switch control circuit that provides a bit line selection signal indicating which pair of bit lines is to be connected to the pair of local data lines.

The local data line selector circuit is formed of multiple switches, whereby each switch has a first pair of terminals connected to one pair of local data lines of the plurality of pairs of local data lines, a second pair of terminals connected to the pair of main data lines that are connected to the differential inputs of the data line sense amplifier, and a control terminal to selectively connect the first pair of terminals to the second pair of terminals so as to selectively connect one pair of the local data lines to the pair of differential inputs.

Each switch is formed of a pair of MOS transistors, whereby the drains of the pair of MOS transistors are connected to the pair of local data lines, sources of the pair of MOS transistors are connected to the pair of main data lines, and gates of the pair of MOS transistors are connected together to form the control terminal and connected to a switch control circuit that provides a local data line selection signal.

The random access memories are generally a dynamic random access memories, but also includes static random access memories and read only memories.

### BRIEF DESCRIPTION OF THE DRAWINGS

FIGS. 1a-1c are diagrams illustrating the structure of a random access memory including the hierarchical data line structure of the prior art.

FIG. 2 is a diagram illustrating the hierarchical data line structure of this invention.

FIG. 3 is a schematic diagram of this invention.

FIG. 4 is a flow chart of the method for selecting a memory data signal of this invention.

### DETAILED DESCRIPTION OF THE INVENTION

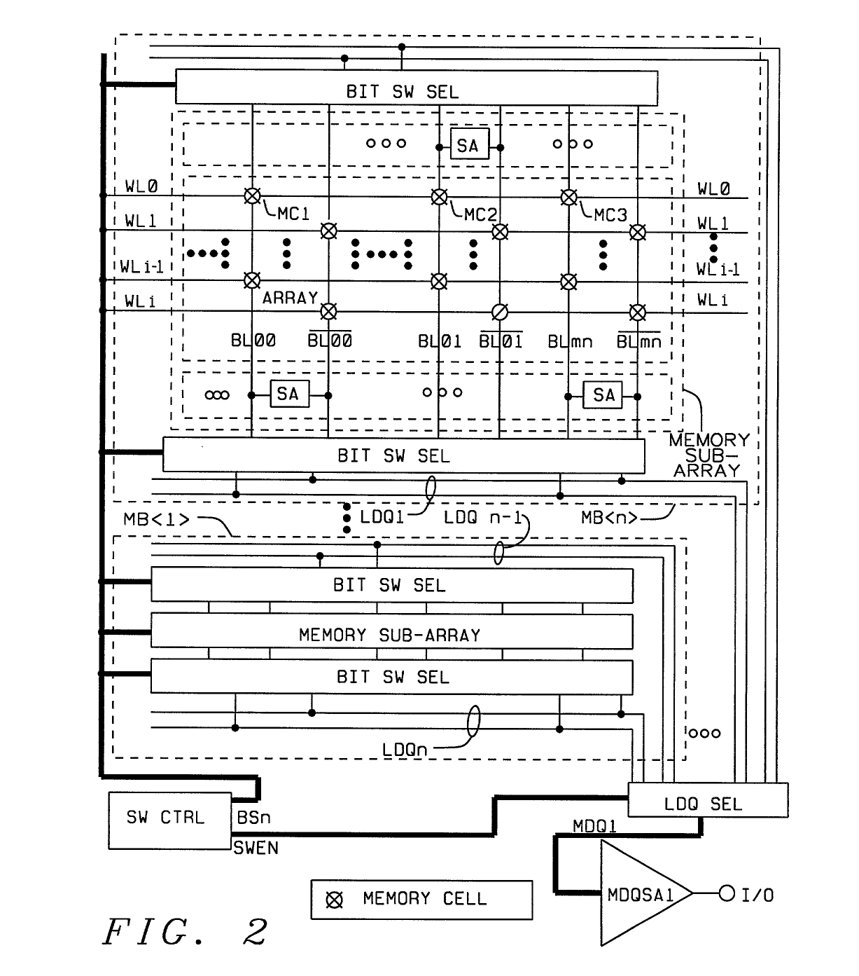

Refer now to FIG. 2 for a discussion of the hierarchical data line structure including the bit line selection circuit of this invention. As described in the prior art, the memory cells are arranged in rows and columns to form each memory sub-array of a memory segment MSeg<n>within a memory block MB<n>. The memory cells of each column are interconnected by the bit lines BL00, \overline{BL00}, BL01, \overline{BL01}, . . . , BLmn, \overline{BLmn}. The memory cells of each row are interconnected by the word lines WL0, . . . , WLi. The bit lines BL00, \overline{BL00}, . . . , BLmn, \overline{BLmn} are paired and connected to the sense amplifiers SA. As described above, during a read operation a selected memory cell transfers its charge as the memory data signal to the sense amplifier SA connected to the bit lines BL00, \overline{BL00}, . . . , BLmn, \overline{BLmn}. The bit lines BL00, \overline{BL00}, . . . , BLmn, \overline{BLmn} associated or paired with the bit line connected to the selected memory cell are set to a reference voltage level and act as a reference voltage source for the sense amplifier SA. The sense amplifier SA senses and amplifies the memory data signal to a level required by the main data line sense amplifier MDQSA1.

Each pair of bit lines BL00, \overline{BL00}, . . . , BLmn, \overline{BLmn} are connected to the bit line switch selection circuit BIT SWSEL. The bit line switch selection circuit BIT SWSEL couples one pair of the bit lines BL00, \overline{BL00}, . . . BLmn, \overline{BLmn} to the appropriate local data lines LDQ0, . . . , LDQn. Each bit line switch selection circuit is connected to the switch control circuit SWCTRL by the bit selection line BSn. The bit selection line BSn selects which of the bit line pairs BL00, \overline{BL00}, . . . , BLmn, \overline{BLmn} are to be coupled through the bit line switch selection circuit to the local data lines LDQ1, . . . , LDQn.

The local data lines LDQ0, . . . , LDQn are connected in turn to the local data line selection circuit (LDQSEL). The local data line selection circuit selects one of the local data lines LDQ0, . . . , LDQn to be connected to the main data line and then to the main data line sense amplifier MDQSA1. The switch control circuit is connected to the local data line switch selection circuit by the switch enable control line SWEN. The state of the switch enable control line SWEN determines which of the local data lines is to be connected to the main data line MDQ1 and thus which memory data signal is to be transferred to the main data line sense amplifier MDQSA1.

The main data line sense amplifier MDQSA1 has an output that is connected to the input/output terminal 110. The main data line sense amplifier MDQSA1 senses, amplifies and converts the memory data signal to voltage and current levels required by external circuitry connected to the input/output terminal I/O.

The switch control circuit decodes and interprets the signals of the memory address bus to choose which pair of bit lines \overline{BL00}, . . . , BLmn, \overline{BLmn} are to be connected to the main data line sense amplifier MDQSA1.

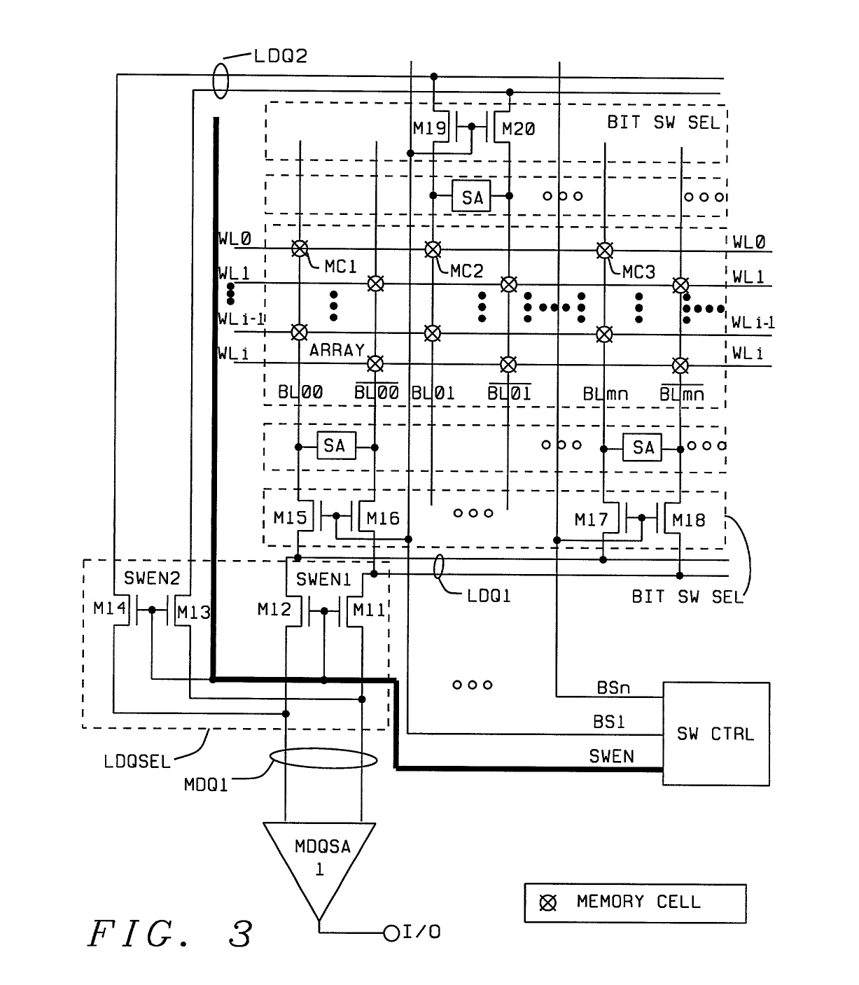

Refer now to FIG. 3 for an embodiment of the bit line selection circuit of this invention. The bit line selection circuit of this invention is formed of the bit line switch selection circuit BIT SWSEL and the local data line selection circuit LDQSEL. The bit line switch selection circuit BIT SWSEL contains multiple switches to selectively connect the pairs of bit lines BL00 and \overline{BL00}, BLmn and \overline{BLmn} to the local data line LDQ1 and the pairs of bit lines BL01 and \overline{BL01} to the local data line LDQ2. Each switch has two terminals connected to one pair of bit lines BL00 and \overline{BL00}, BL01 and \overline{BL01}, or BLmn and \overline{BLmn}, a pair of terminals connected to the local data lines LDQ1 or LDQ2, and a control line connected to the bit select signal line BSn.

The multiple switches of the bit line switch selection circuit are each formed by pairs of MOS transistors M15 and M16, M17 and M18, M19 and M20. The drains of each pair of MOS transistors M15 and M16, M17 and M18, M19 and M20 are connected respectively to the bit line pairs BL00 and \overline{BL00}, BL01 and \overline{BL01}, BLmn and \overline{BLmn}. The sources of the pairs of MOS transistors M15 and M16, M17 and M18 are connected to the local data line LDQ1 and the pair of MOS transistors M19 and M20 is connected to the local data line LDQ2. The gates of the MOS transistors M15 and M16 and M19 and M20 are connected to the bit select signal line BS1. The gates of the MOS transistors M17 and M18 are connected to the bit select signal line BSn.

The pairs of local data lines LDQ1 and LDQ2 are connected to the local data line selection circuit LDQSEL. The local data line selection circuit LDQSEL is formed from multiple switches. Each switch has one pair of terminals connected to a pair of data lines LDQ1, . . . , LDQ2, a second pair of terminals connected to the main data line MDQ1, and a control terminal connected to the switch control circuit with a switch control enable line SWEN. The switches are formed of the pairs of MOS transistors M11 and M12, M13 and M14. The drains of the pairs of MOS transistors M11 and M12 are connected to the pair of local data lines LDQ1. The drains of the pairs of MOS transistors M13 and M14 are connected to the pair of local data lines LDQ2. The sources of the pair of MOS transistors M11 and M12 and the pair of MOS transistors M13 and M14 are respectively connected together and to the pair of main data lines MDQ1 and MDQ2 then to the input of the main data line sense amplifier MDQSA1.

The main data line sense amplifier MDQSA1 senses the amplitude of the memory data signal present on the pair of main data lines MDQ1 and amplifies and converts the memory signal to the voltage and current levels required by external circuitry connected to the input/output terminal I/O.

The gates of the pair of MOS transistors M11 and M12 and the pair of MOS transistors M13 and M14 are respectively connected together and to the switch control circuit through the switch enable control signals SWEN1 and SWEN2.

The bit line selection circuit of this invention functions as follows. The word line WL0, for example, is set to a voltage level such that the memory cells MC1, MC2, and MC3 are activated. The charge present on the memory cells MC1, MC2, and MC3 is transferred respectively to the bit lines BL00, BL01, and BLmn. The bit lines \overline{BL00}, \overline{BL01}, and \overline{BLmn} act as the reference voltage sources for the bit line sense amplifier SA connected to each pair of bit lines BL00 and \overline{BL00}, BLO1 and \overline{BL01}, BLmn and \overline{BLmn}, The bit line sense amplifier senses the charge transferred from the memory cells MC1, MC2 and MC3 and amplifies the charge to create the memory data signal present on the pairs of bit lines BL00 and \overline{BL00}, BL01 and \overline{BL01}, BLmn and \overline{BLmn}. If the memory cells MC1 and MC2 are to be read, the bit select line BS1 is activated to turn on the pair of MOS transistors M15 and M16 and the pair of MOS transistors M19 and M20. The activated pair of MOS transistors M15 and M16 couple the memory data signal from the memory cell MC1 to the local data line LDQ1. The activated pair of MOS transistors M19 and M20 couple the memory data signal from memory cell MC2 to the local data line LDQ2.

Based on the address of the desired memory cell, the switch enable control signals SWEN1 and SWEN2 activates the appropriate pair of MOS transistors M1 and M12 or M13 and M14 local data line selector circuit LDQSEL to transfer the memory data signal from the local data lines LDQ1 or LDQ2 to the main data line MDQ1 and then to the main data line sense amplifier MDQSA1. For example, if at a first period the memory data signal from the charge present on the memory MC1 is to be read, the switch enable control signal SWEN1 is set to a voltage level that will activate the pair of MOS transistors M11 and M12. The memory data signal present on the local data line LDQ1 is transferred to the main data line MDQ1. The main data line sense amplifier MDQSA1 senses the memory data signal from the local data line LDQ1 that originated from the memory cell MC1, amplifies the memory data signal, and converts it to a voltage and signal level suitable for external circuitry connected to the input/output terminal I/O.

If the memory data signal that originated from the memory cell MC2 is desired, the switch control circuit deactivates the switch enable control signal SWEN1 and activates the switch enable control signal SWEN2 such that the memory data signal from the local data line LDQ2 is transferred to the main data line MDQ1 and then to the main data line sense amplifier MDQSA1 to be converted to the voltage and current level required by the external circuitry connected to the input/out terminal I/O.

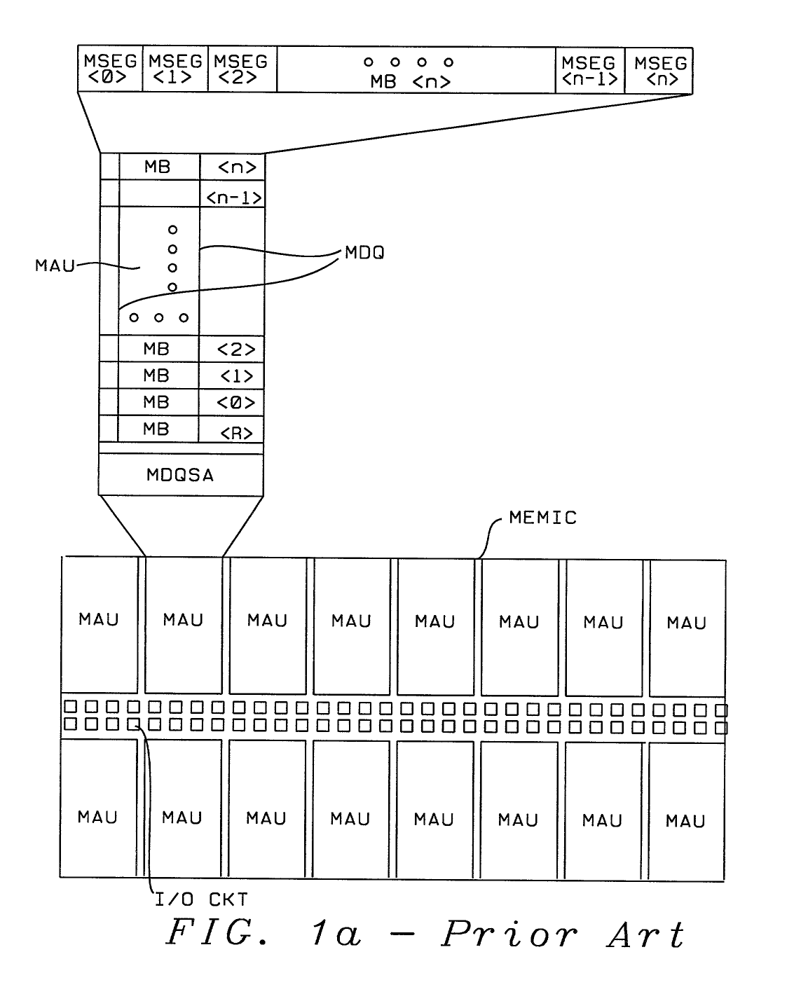

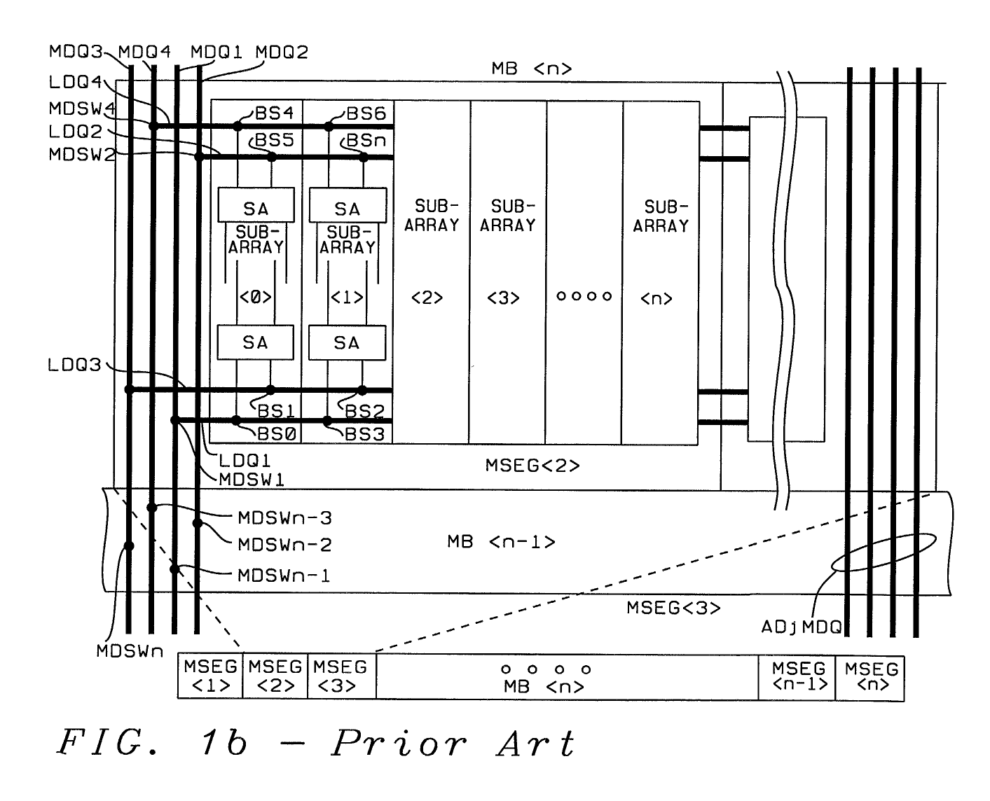

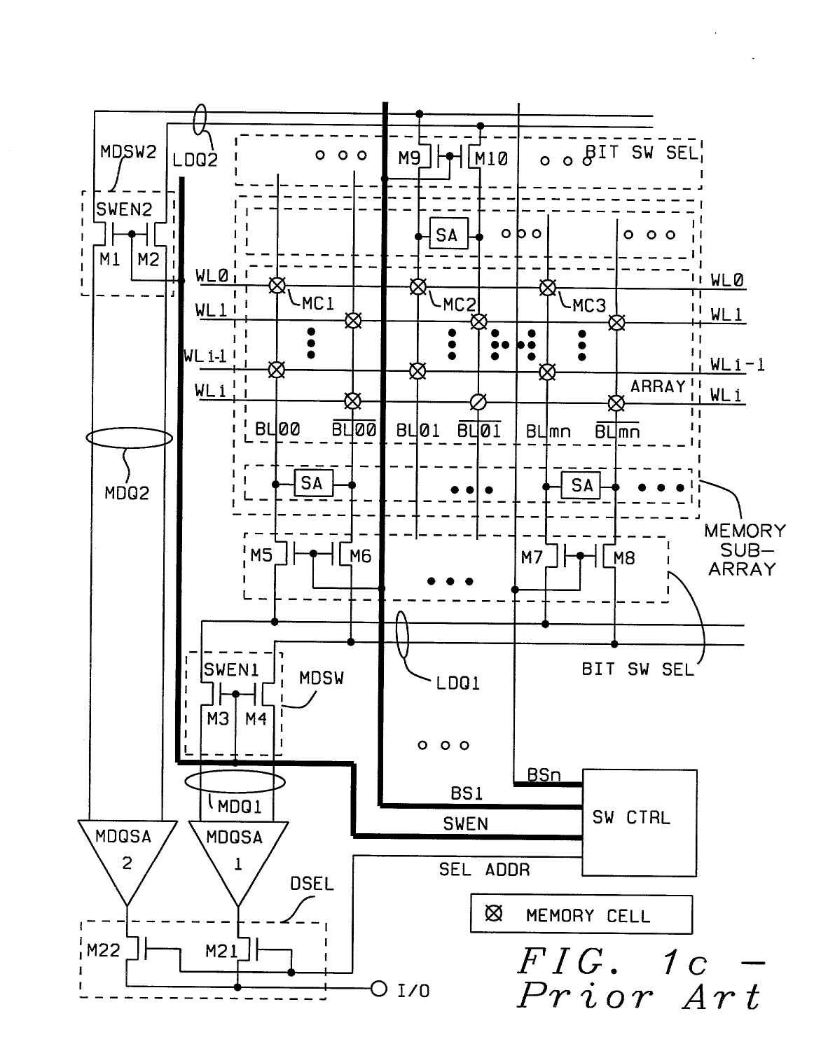

As is apparent from the above description, the hierarchical data line structure with the bit line selection circuit of this invention allows fewer main data lines MDQ and main data line sense amplifiers MDQSA to accomplish the transfer of the memory data signals from the memory cells during a read operation Further, the simplified structure allows reading of multiple memory cells of memory cell. Additionally, the switch control circuitry is simplified by the elimination of the select address control line of FIG. 1c.

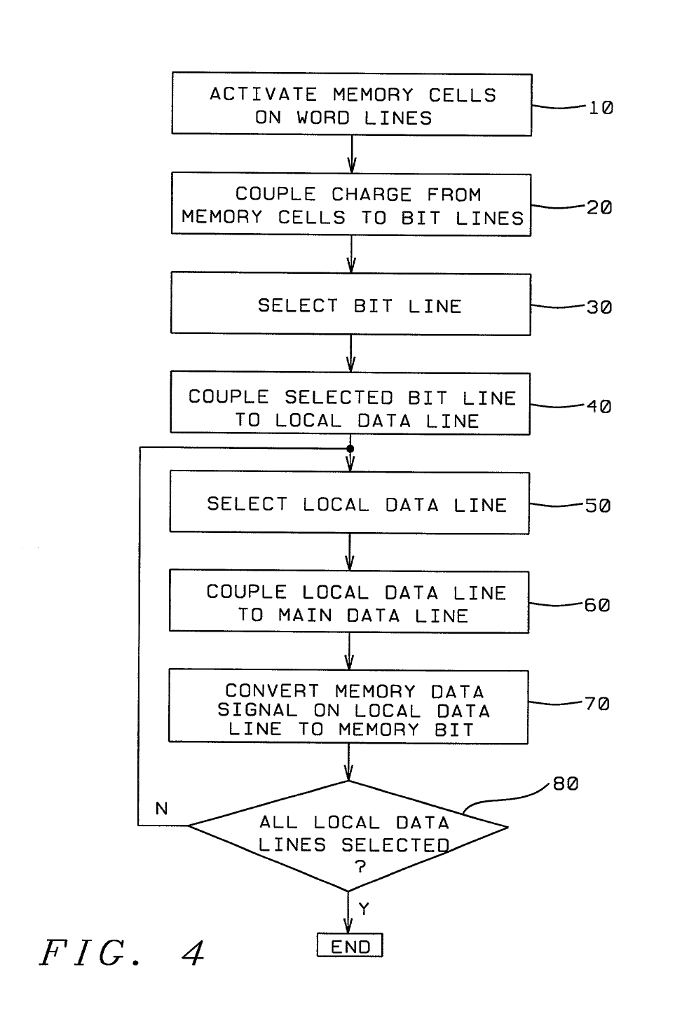

To review the method of selecting a memory data signal, which represents the charge of a desired memory cell, refer now to FIG. 4. The method begins with the activation 10 of all memory cells on a word line of an array of memory cells. The charge present on the activated memory cell is coupled 20 to bit lines connected to the activated memory cells. The pair of bit lines containing the desired data memory signal is selected 30 from the multiple bit lines to couple 40 the selected pair of bit lines to one pair of local data lines. One of the pairs of local data lines is selected 50 and coupled 60 through the pair of main data lines to the input of the data line sense amplifier. The main data line send amplifier converts 70 the memory data signal to an appropriate signal level required to be a memory bit. Each desired data is iteratively selected 50 until the last local data line is selected 80.

While this invention has been particularly shown and described with reference to the preferred embodiments thereof, it will be understood by those skilled in the art that various changes in form and details may be made without departing from the spirit and scope of the invention.

The invention claimed is:

1. A bit line selection circuit connected between a plurality of pairs of bit lines of a plurality of sub-arrays of a random access memory and a main data line sense amplifier comprising:
a local data line selector circuit to select one of a plurality of pairs of local data lines to be connected to a pair of main data lines connected to the main data line sense amplifier, whereby each pair of local data lines is selectively coupled to one pair of bit lines of the pairs of bit lines.

2. The circuit of claim 1 further comprising:
a bit line selector circuit to selectively couple one pair of bit lines of the plurality of bit lines of each sub-array to the pair of local data lines.

3. The circuit of claim 1 wherein the local data line circuit comprises a first plurality of switches, whereby each switch a first pair of terminals connected to one pair of local data lines of the plurality of pairs of local data lines, a second pair of terminals connected to the pair of main data lines connected to a pair of inputs of the main data line sense amplifier, and a control terminal to selectively connect the first pair of terminals to the second pair of terminals so as to selectively connect one pair of the local data lines to the pair of main data lines.

4. The circuit of claim 3 wherein each switch comprises a pair of MOS transistors, whereby drains of the pair of MOS transistors are connected to the pair of local data lines, sources of the pair of MOS transistors are connected to the pair of main data lines, and gates of the pair of MOS transistors are connected together to form the control terminal and connected to a switch control circuit that provides a local data line selection signal.

5. The circuit of claim 2 wherein the bit line selector circuit comprises a second plurality of switches, whereby each switch of said second plurality of switches has a first pair of terminals connected to one pair of the pairs of bit lines, a second pair of terminals connected to one of the pair of local data lines, and a control terminal to selectively connect the first pair of terminals to the second pair of terminals to couple the pair of bit lines to the pair of local data lines.

6. The circuit of claim 5 wherein each switch of the plurality of switches comprises a pair of MOS transistors, whereby said pair of MOS transistors has a pair of drains connected the pair of bit lines, a pair of sources connected to the pair of local data lines, and a pair of gates connected together to form said control terminal, and connected to the switch control circuit that provides a bit line selection signal indicating which pair of bit lines is to be connected to the pair of local data lines.

7. The circuit of claim 1 wherein the random access memory is selected from the group of random access memories consisting of static random access memories, dynamic random access memories, and read only memories.

8. A random access memory comprising:
at least one sub-array of memory cells arranged in rows and columns such that pairs of columns of memory cells are interconnected by pairs of bit lines;
a plurality of pairs of local data lines coupled to the pairs of bit lines;
a data line selector circuit to select one of a plurality of pairs of local data lines to be connected to a pair of main data lines connected to the main data line sense amplifier, whereby each pair of local data lines is selectively coupled to one pair of bit lines of the pairs of bit lines; and
a bit line selection circuit to selectively couple one pair of bit lines of the plurality of bit lines of each sub-array to the pair of local data lines.

9. The memory of claim 8 wherein the local data line circuit comprises a first plurality of switches, whereby each switch a first pair of terminals connected to one pair of local data lines of the plurality of pairs of local data lines, a second pair of terminals connected to the pair of main data lines connected to a pair of inputs of the main data line sense amplifier, and a control terminal to selectively connect the first pair of terminals to the second pair of terminals so as to selectively connect one pair of the local data lines to the pair of main data lines.

10. The memory of claim 9 wherein each switch comprises a pair of MOS transistors, whereby drains of the pair of MOS transistors are connected to the pair of local data lines, sources of the pair of MOS transistors are connected to the pair of main data lines, and gates of the pair of MOS transistors are connected together to form the control terminal and connected to a switch control circuit that provides a local data line selection signal.

11. The memory of claim 8 wherein the bit line selector circuit comprises a second plurality of switches, whereby each switch of said second plurality of switches has a first pair of terminals connected to one pair of the pairs of bit lines, a second pair of terminals connected to one of the pair of local data lines, and a control terminal to selectively connect the first pair of terminals to the second pair of terminals to couple the pair of bit lines to the pair of local data lines.

12. The memory of claim 11 wherein each switch of the plurality of switches comprises a pair of MOS transistors, whereby said pair of MOS transistors has a pair of drains connected the pair of bit lines, a pair of sources connected to the pair of local data lines, and a pair of gates connected together to form said control terminal, and connected to the switch control circuit that provides a bit line selection signal indicating which pair of bit lines is to be connected to the pair of local data lines.

13. The memory of claim 8 wherein the memory cells are selected from the group of random access memories consisting of static random access memories, dynamic random access memories, and read only memories.

14. A bit line coupling apparatus to selectively couple a pair of bit lines, which interconnect a grouping of memory cells, to a main data line sense amplifier, comprising:
a bit line selection means connected to a plurality of pairs of bit lines to select the pair of bit lines to be coupled;
a plurality of pairs of local data lines connected to the bit line selection means to convey a memory data signal from a selected pair of data line; and
a data line selection means connected between the plurality of pairs of local data lines and the main data line sense amplifier to select one of the pair of local data lines to be coupled to the main data line sense amplifier to convey the memory data signal to the sense amplifier to be sensed and amplified to a memory data bit.

15. The apparatus of claim 14 wherein the local data line circuit comprises a first plurality of switches, whereby each switch a first pair of terminals connected to one pair of local data lines of the plurality of pairs of local data lines, a second pair of terminals connected to the pair of main data lines connected to a pair of inputs of the main data line sense amplifier, and a control terminal to selectively connect the first pair of terminals to the second pair of terminals so as to selectively connect one pair of the local data lines to the pair of main data lines.

16. The apparatus of claim 15 wherein each switch comprises a pair of MOS transistors, whereby drains of the pair of MOS transistors are connected to the pair of local data lines, sources of the pair of MOS transistors are connected to the pair of main data lines, and gates of the pair of MOS transistors are connected together to form the control terminal and connected to a switch control circuit that provides a local data line selection signal.

17. The apparatus of claim 14 wherein the bit line selector circuit comprises a second plurality of switches, whereby each switch of said second plurality of switches has a first pair of terminals connected to one pair of the pairs of bit lines, a second pair of terminals connected to one of the pair of local data lines, and a control terminal to selectively connect the first pair of terminals to the second pair of terminals to couple the pair of bit lines to the pair of local data lines.

18. The apparatus of claim 17 wherein each switch of the plurality of switches comprises a pair of MOS transistors, whereby said pair of MOS transistors has a pair of drains connected the pair of bit lines, a pair of sources connected to the pair of local data lines, and a pair of gates connected together to form said control terminal, and connected to the switch control circuit that provides a bit line selection signal indicating which pair of bit lines is to be connected to the pair of local data lines.

19. The apparatus of claim 14 wherein the memory cells are selected from the group of random access memories consisting of static random access memories, dynamic random access memories, and read only memories.

20. A method for selection of a data memory signal for transfer from a selected memory cell connected to one bit line of a pair of bit lines to a main data line sense amplifier, comprising the steps of:
selecting the pair of bit lines containing the data memory signal from a plurality of pairs of bit lines;
coupling said selected pair of bit lines to one pair of local data lines of a plurality of pairs of local data lines;
selecting the pair of local data lines of the plurality of local data lines; and
connecting the selected pair of local data lines to the main data line sense amplifier.

21. The method of claim 20 wherein the selecting and coupling of the pair of bit line to the local data lines is performed by a bit line selector circuit to selectively couple one pair of bit lines of the plurality of bit lines of each sub-array to the pair of local data lines.

22. The method of claim 20 wherein the selection and connecting of the pair of local data lines is performed by a local data line selection circuit to select one of a plurality of pairs of local data lines to be connected to a pair of main data lines connected to the main data line sense amplifier, whereby each pair of local data lines is selectively coupled to one pair of bit lines of the pairs of bit lines.

23. The method of claim 21 wherein the bit line selector circuit comprises a second plurality of switches, whereby each switch of said second plurality of switches has a first pair of terminals connected to one pair of the pairs of bit lines, a second pair of terminals connected to one of the pair of local data lines, and a control terminal to selectively connect the first pair of terminals to the second pair of terminals to couple the pair of bit lines to the pair of local data lines.

24. The method of claim 23 wherein each switch of the plurality of switches comprises a pair of MOS transistors, whereby said pair of MOS transistors has a pair of drains connected the pair of bit lines, a pair of sources connected to the pair of local data lines, and a pair of gates connected together to form said control terminal, and connected to the switch control circuit that provides a bit line selection signal indicating which pair of bit lines is to be connected to the pair of local data lines.

25. The method of claim 22 wherein the local data line circuit comprises a first plurality of switches, whereby each switch a first pair of terminals connected to one pair of local data lines of the plurality of pairs of local data lines, a second pair of terminals connected to the pair of main data lines connected to a pair of inputs of the main data line sense amplifier, and a control terminal to selectively connect the first pair of terminals to the second pair of terminals so as to selectively connect one pair of the local data lines to the pair of main data lines.

26. The method of claim 25 wherein each switch comprises a pair of MOS transistors, whereby drains of the pair of MOS transistors are connected to the pair of local data lines, sources of the pair of MOS transistors are connected to the pair of main data lines, and gates of the pair of MOS transistors are connected together to form the control terminal and connected to a switch control circuit that provides a local data line selection signal.

27. The method of claim 20 wherein the selected memory cells is selected from the group of memory cells consisting of dynamic random access memory cells, static random access memory cells, and read only memory cells.
